(19) United States
(12) Patent Application Publication
(10) Pub. No.: US 2015/0349742 A1
(43) Pub. Date: Dec. 3, 2015

(54) ADAPTIVE LOAD FOR COUPLER IN BROADBAND MULTIMODE MULTI-BAND FRONT END MODULE

(71) Applicant: SKYWORKS SOLUTIONS, INC., Woburn, MA (US)

(72) Inventors: David Ruimin CHEN, Oak Park, CA (US); Shiaw Wen CHANG, Thousand Oaks, CA (US); Ede Peter ENOBAKHARE, Camarillo, CA (US); Brian Blu DUVERNEAY, Wyoming, MI (US)

(21) Appl. No.: 14/723,886

(22) Filed: May 28, 2015

Related U.S. Application Data
(60) Provisional application No. 62/004,325, filed on May 29, 2014.

(51) Int. Cl. H03H 7/46; H04L 5/08; H03H 7/38

(52) U.S. Cl. CPC H03H 7/468; H03H 7/38; H04L 5/08; H03H 2007/386; H04W 88/06

(57) ABSTRACT

Directional couplers for front end modules (FEMs) are disclosed that include a first port configured to receive a radio-frequency (RF) signal, a second port connected to the first port via a first transmission line and configured to provide an RF output signal, and a third port connected to a second transmission line, the second transmission line coupled to the first transmission line. A directional coupler in accordance with the present disclosure may further include a termination circuit connected to the second transmission line and configured to provide a first impedance when the RF signal is within a first frequency band and provide a second impedance when the RF signal is within a second frequency band.

### RELATED APPLICATION

This application claims priority to U.S. Provisional Application No. 62/004,325, filed on May 29, 2014, entitled ADAPTIVE LOAD FOR COUPLER IN BROADBAND MULTIMODE MULTI-BAND FRONT END MODULE, the disclosure of which is hereby incorporated by reference in its entirety.

### BACKGROUND

1. Field

The present disclosure generally relates to front end modules in radio-frequency (RF) devices.

2. Description of Related Art

Directional couplers can be used in connection with front end modules (FEMs) in certain RF devices. Output power control accuracy in FEMs can be adversely affected by various design and/or operational factors.

### SUMMARY

In some implementations, the present disclosure relates to directional couplers for use with front end modules in radio-frequency (RF) devices. Certain embodiments provide a directional coupler including a first port configured to receive an RF signal, a second port connected to the first port via a first transmission line and configured to provide an RF output signal, and a third port connected to a second transmission line, the second transmission line coupled to the first transmission line. The directional coupler further includes a termination circuit connected to the second transmission line and configured to provide a first impedance when the RF signal is within a first frequency band and provide a second impedance when the RF signal is within a second frequency band.

In certain embodiments, the termination circuit includes first and second passive devices that are configured to resonate at a frequency within the first frequency band. The first passive device may be a resistor and the second passive device may be a capacitor. In certain embodiments, the first passive device may be a resistor and the second passive device may be an inductor.

In certain embodiments, the termination circuit further includes a third passive device in parallel with the first and second passive devices. The first passive device may be a resistor, one of the second and third passive devices may be a capacitor and another of the second and third passive devices may be an inductor. In certain embodiments, the first and second impedances are complex impedances. In certain embodiments, the termination circuit includes a diplexer for selectively connecting the second transmission line to the first or second impedance.

Certain embodiments provide a radio-frequency (RF) system including a directional coupler configured to provide an RF output signal on a first port of the directional coupler, a power amplifier module connected to a second port of the directional coupler, and power detection circuitry connected to a third port of the directional coupler. The RF system further includes a termination circuit connected to a fourth port of the directional coupler and configured to provide a first impedance when the RF output signal is within a first frequency band and provide a second impedance when the RF signal is within a second frequency band.

The termination circuit may include first and second passive devices are configured to resonate at a frequency within the first frequency band. The first passive device may be an inductor and the second passive device may be a capacitor. In certain embodiments, the termination circuit further includes a third passive device in parallel with the first and second passive devices. In certain embodiments, one of the first and second passive devices is a capacitor and another of the first and second passive devices is an inductor and the third passive devices is a resistor.

In certain embodiments, the first and second impedances are complex impedances. The termination circuit may include a diplexer for selectively connecting the second transmission line to the first or second impedance.

Certain embodiments provide a wireless device including a transceiver configured to process RF signals, an antenna in communication with the transceiver configured to facilitate transmission of an RF output signal, and a directional coupler configured to provide the RF output signal to the antenna on a first port of the directional coupler. The wireless device further includes a power amplifier module connected to a second port of the directional coupler, a power detection circuitry connected to a third port of the directional coupler, and a termination circuit connected to a fourth port of the directional coupler and configured to provide a first impedance when the RF output signal is within a first frequency band and provide a second impedance when the RF signal is within a second frequency band.

The termination circuit may include first and second passive devices that are configured to resonate at a frequency within the first frequency band. For example, the first passive device may be a capacitor and the second passive device may be an inductor. In certain embodiments, the termination circuit further includes a third passive device in parallel with the first and second passive devices.

Certain embodiments disclosed herein provide a process for operating a directional coupler, the process including receiving a radio-frequency (RF) signal on a first port of the directional coupler, providing at least a first portion of the RF signal to a second port of the directional coupler connected to the first port via a first transmission line, and coupling at least a second portion of the RF signal to a second transmission line, the second transmission line connecting between third and fourth ports of the directional coupler. The process may further involve providing a termination circuit connected to the second transmission line at either the third or fourth port and configured to provide a first impedance when the second portion of the RF signal is within a first frequency band and provide a second impedance when the second portion of the RF signal is within a second frequency band.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 is a block diagram of a front-end module (FEM) for an RF device according to one or more embodiments.

FIG. 2 is a block diagram of a directional coupler according to one or more embodiments.

FIG. 3 is a block diagram showing a plurality of directional couplers in a “daisy chain” configuration according to one or more embodiments.

FIG. 4 is a block diagram of a power amplifier FEM according to one or more embodiments.

FIG. 5 is a diagram illustrating possible coupler error load-pull result for an RF system according to one or more embodiments.

FIG. 6 is a diagram illustrating an adaptive load circuit according to one or more embodiments.

FIG. 7 is a diagram illustrating an adaptive load circuit according to one or more embodiments.

FIG. 8 is a block diagram of a front end module incorporating a directional coupler according to one or more embodiments.

FIG. 9 schematically depicts a wireless device according to one or more embodiments.

### DETAILED DESCRIPTION

The headings provided herein are for convenience only and do not necessarily affect the scope or meaning of the claimed invention. Disclosed herein are example configurations and embodiments relating to adaptive loads for directional couplers in front end modules.

The demand and usage associated with mobile internet and multimedia services has expanded significantly in recent years. Mobile web browsing, music and video downloading/streaming, video teleconferencing, social networking, gaming, broadcast television, and other mobile services are examples of common mobile internet usages. To accommodate such mobile connectivity applications, various advanced mobile devices have been developed, including smart phones, PDAs, netbooks, tablet PCs and data cards, and others.

Mobile devices may be configured to support various wireless standards, including, for example, 3G WCDMA/HSPA and 4G LTE standards, and may also be configured to support backward compatibility with the legacy 2G GSM and 2.5G GPRS/EDGE standards. Furthermore, such devices may support a plurality of frequency bands, and may be required to do so while maintaining relatively low cost and/or size. Increased complexity of mobile devices can result in more stringent requirements with respect to the design of front end module (FEM) components, such as filters, switches and/or power amplifier modules (PAM). For example, certain PAMs in handsets and other mobile devices are designed to accommodate a quad-band GSM/GPRS/EDGE PAM plus one or more single-mode, single-band 3G PAMs. In certain embodiments, a FEM/PAM may be configured to support all relevant air interface standards while covering all relevant frequency bands.

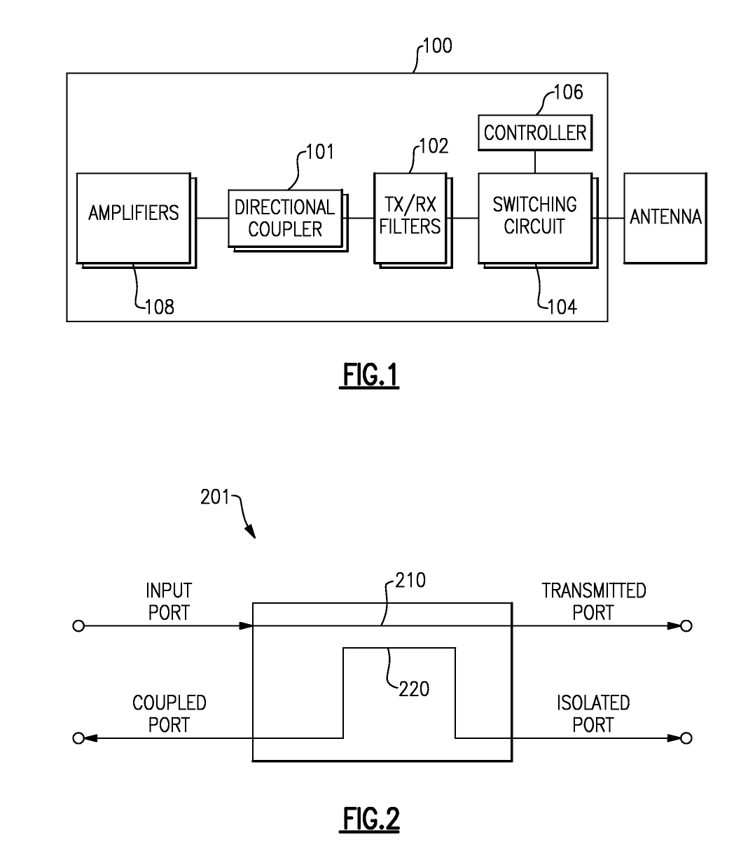

Front end modules designed to provide multiband multimode functionality may comprise various components designed to accommodate such functionality. FIG. 1 provides an illustration of an embodiment of a front-end module (FEM) 100 for an RF device such as a wireless device, which may implement one or more features described herein. The FEM 100 may be a multimode, multiband (MMMB) front end module. The FEM 100 may include an assembly 102 of transmitting (TX) and/or receiving (RX) filters. The FEM 100 can also include one or more switching circuits 104. In some embodiments, control of the switching circuit(s) 104 can be performed or facilitated by a controller 106. The FEM 100 can be configured to be in communication with an antenna, or with a plurality of antennas. In some implementations, the FEM 100 can be included in an RF device such as a wireless device. The FEM can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, a wearable wireless computing device, etc.

The FEM 100 includes one or more amplifiers 108 or amplifier modules coupled to one or more directional couplers 101. Directional couplers may be used in radio frequency (RF) power amplifier applications for coupling part of the transmission power in a transmission line by a certain amount out through another port. In the case of microstrip or stripline couplers, described in further detail below, such coupling is achieved by using two transmission lines set close enough together such that energy passing through one is coupled to the other. Generally speaking, power coupling and control architectures for handsets can be broken down into two primary groups: direct and indirect detection. Indirect power detection measures DC characteristics without directly evaluating the RF output power. Relatively simple circuitry associated with indirect detection can offer a lower cost and/or smaller size solution. However, in certain embodiments, indirect detection systems can suffer from control accuracy issues due to unpredictable antenna loading conditions. In contrast, direct power detection monitors the RF waveform itself, and often requires a directional coupler and associated design complexity. Couplers can be implemented with discrete components or embedded on a printed circuit board.

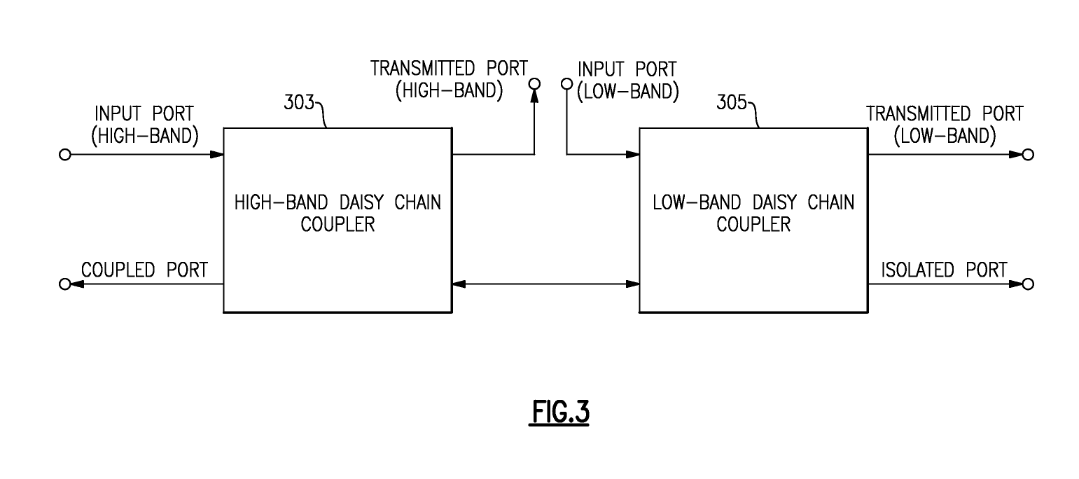

As illustrated in FIG. 2, a directional coupler 201 may include four ports, namely an input port, a transmitted port, a coupled port, and an isolated port. The term “main line,” as used herein, may refer to the transmission line section 210 of the coupler between the input and transmitted ports. The term “coupled line,” as used herein, may refer to the transmission line section 220 that runs parallel to the main line 210 and between the coupled and isolated ports.

Although the various ports are illustrated in a particular configuration in FIG. 2, directional coupler ports may take on other configurations while still providing coupling functionality. That is, the various notations of FIG. 2 may be considered arbitrary in certain applications. For example, any given port may be considered the input port, wherein the directly connected port becomes the transmitted port, the adjacent port becomes the coupled port, and the diagonal port becomes the isolated port (e.g., for stripline and/or microstrip couplers).

An input radio frequency (RF) signal may be supplied at the input port of the coupler from an RF generator of some kind. For example, the input signal may be driven at least in part by one or more power amplifier devices coupled to the input port. The majority of this input signal may be passed via the main arm 210 of the coupler 201 to a signal recipient coupled to the transmitted port, and a portion of the signal, for example 1% of the signal for a 20 dB coupler, may be supplied via the coupled arm 220 to a detector coupled to the coupled port. The devices acting as the RF generator, signal transmitted signal recipient, and detector, and configurations thereof, may depend on the system in which the coupler 201 is used. For example, the RF generator that supplies the input signal to the input port may be a power amplifier, a switch, a transceiver, or any other device from which it may be desirable to take a sample (e.g., at the coupled port) of its output signal. The transmitted signal may be received by, for example, a switch, another power amplifier, an antenna, a filter, and/or the like. By providing a sample of the RF input signal at the coupled port, the coupler 201 may provide a mechanism for measuring the RF input signal. The coupled port may be connected to any desirable type of detector, such as, for example, a sensor or feedback controller configured to use the signal detected at the coupled port to provide information to the system and/or to adjust/control the RF input signal.

The isolated port may be terminated with an internal or external matched load, such as a 50 Ohm or 75 Ohm load, for example. However, terminating the coupler isolation port with 50 Ohm may not provide ideal coupler performance when the transmitted port is not ideal and/or the coupler directivity is finite. Therefore, certain embodiments disclosed herein provide complex impedance termination circuitry which may be adapted to provide desirable coupler performance. Furthermore, the termination circuitry may be adaptable to provide different load impedance for different bands and/or modes of operation where more than one band of operation is included in a single power amplifier module. For example, due to space or other considerations, multiple operational bands may share a single directional coupler. In certain embodiments, a multimode multiband (MMMB) FEM cascade with a duplexer can suffer from detector error that degrades significantly at one or more bands due to the impedance at the coupler output port changing with frequency and the duplexer and antenna switch module (ASM). Therefore, accuracy over multiple bands for directional couplers may be a significant consideration.

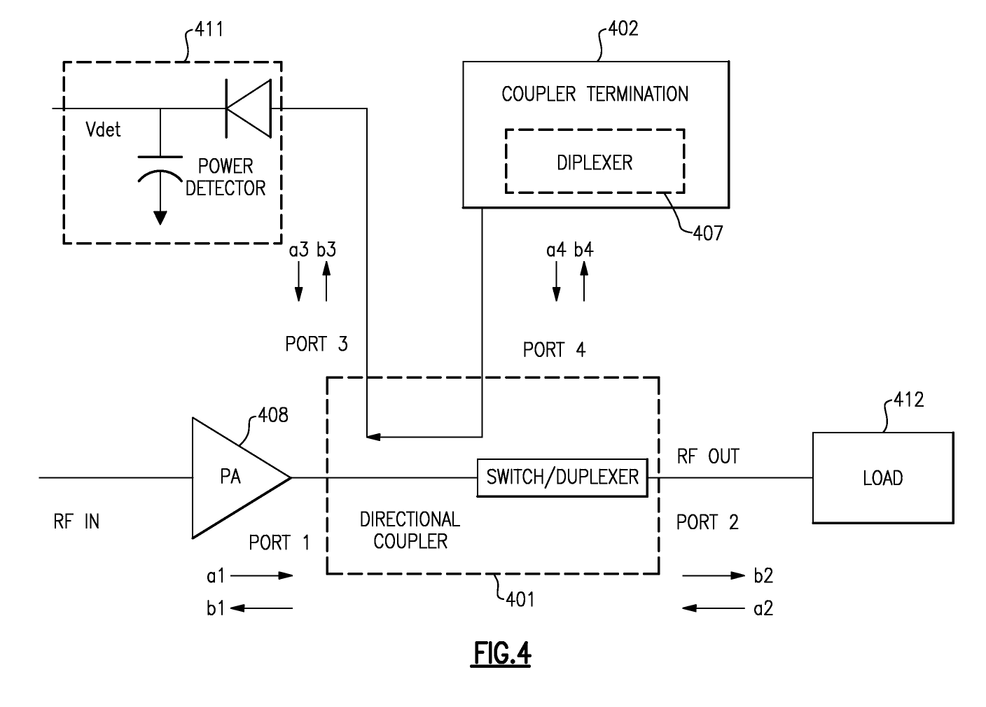

An MMMB FEM may utilize one or more directional couplers in a “daisy chain” configuration, as illustrated in FIG. 3. In certain embodiments, multi-band and multi-mode architectures for wireless devices, such as cellular telephone handsets, provide power detection that is shared across multiple frequency bands using “daisy-chained” directional couplers. Such configurations may necessitate couplers with high directivity as well as substantially similar coupling factors across different frequency bands. In a daisy chain configuration, as shown in FIG. 3, a terminating port of a directional coupler (e.g., a high-band coupler 303) may be electrically connected to the coupled port of a second directional coupler (e.g., a low-band coupler 305), such that the two couplers share a termination impedance. Although only two directional couplers are illustrated in FIG. 3, principles disclosed herein may be utilized in configurations comprising any number of couplers, such as three or more. Embodiments of coupler isolation circuits disclosed herein may be utilized to provide shared isolation for a plurality of daisy-chain couplers.

Power control requirements of WCDMA, GSM/EDGE, and/or other types of systems can introduce challenges in power amplifier (PA) front end module (FEM) design. For example, although output power control accuracy is often a clearly-defined design specification, the interaction of control bandwidth, switching spectrum and mismatched load are often not fully investigated until late in the product development cycle; such concerns are often among the last few design specifications worked out near the end of a design cycle. State-of-the-art multi-mode and multi-band handset PA FEMs may require dynamic range over 40 dB, with, for example, +/−0.5 dB power control accuracy at a mismatched load.

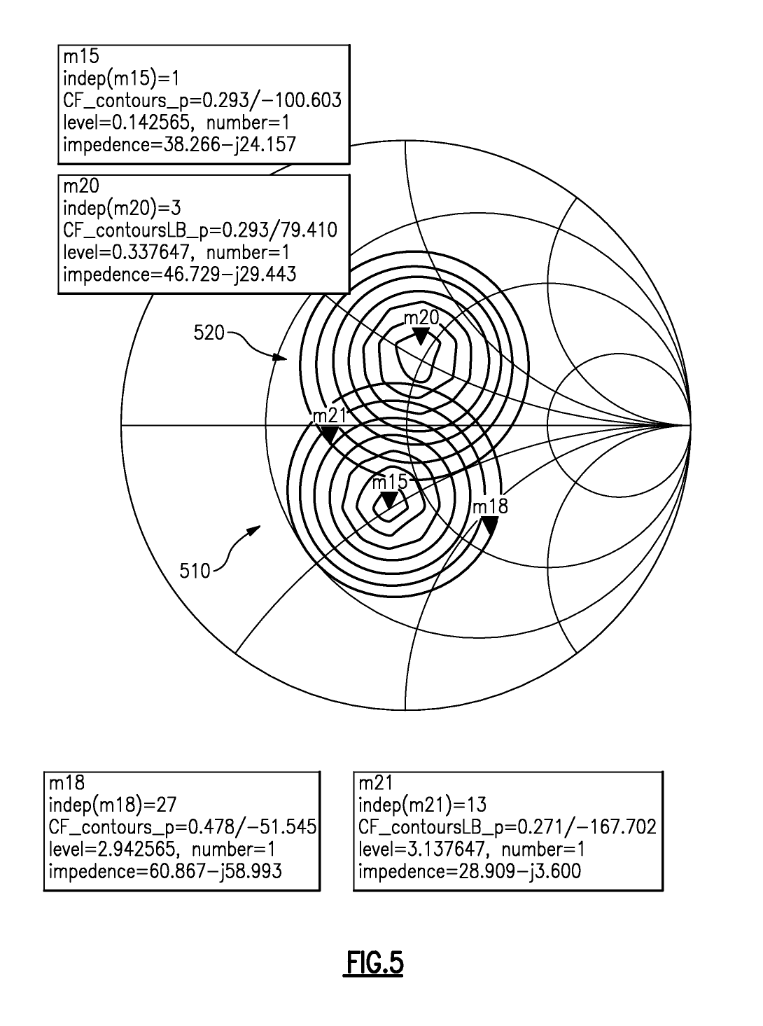

FIG. 4 illustrates an embodiment of a power amplifier FEM with directional coupler 401. The illustrated system may correspond to a generic power amplifier FEM with a directional coupler for output power detection and control. Such a FEM may be applicable to GSM/EDGE (e.g., with a switch after the directional coupler 401) or WCDMA (e.g., with a duplexer after the directional coupler 401). The associated antenna/mismatch load may be denoted herein as Γ_{L}, and the coupler termination 402 may be denoted herein as Γ_{CT}.

The 4-port directional coupler system 401 may be represented by the following equation, which illustrates a general 4-port scattering matrix:

$$( \begin{matrix}b 1 \\ b 2 \\ b 3 \\ b 4\end{matrix} ) = ( \begin{matrix}S 11 & S 12 & S 13 & S 14 \\ S 21 & S 22 & S 23 & S 24 \\ S 31 & S 32 & S 33 & S 34 \\ S 41 & S 42 & S 43 & S 44\end{matrix} ) * ( \begin{matrix}a 1 \\ a 2 \\ a 3 \\ a 4\end{matrix} )$$

In certain PA FEM system embodiments, the coupling port (Port 3) may be matched to a 50-ohm coupling termination, such that a3 may be considered to equal 0 for simplicity. Therefore, the matrix can be simplified as follows:

$$( \begin{matrix}b 1 \\ b 2 \\ b 3 \\ b 4\end{matrix} ) = ( \begin{matrix}S 11 & S 12 & S 13 & S 14 \\ S 21 & S 22 & S 23 & S 24 \\ S 31 & S 32 & S 33 & S 34 \\ S 41 & S 42 & S 43 & S 44\end{matrix} ) * ( \begin{matrix}a 1 \\ a 2 \\ 0 \\ a 4\end{matrix} )$$

where b2 represents the forward voltage wave at RF OUT (Port 2), and b3 represents the forward voltage wave at the coupling port for PA FEM power control. When the load changes, the system may adjust al to maintain b3, which may be referenced to a b3 value measured with a 50 ohm load (i.e., Γ_{L}=0).

Coupler directivity can be defined by the following equation:

$$D = \frac{S 31}{S 32}$$

The scattering matrix above may be simplified as follows:

$$\frac{b 2}{b 3} ≅ \frac{S 21}{S 31 - ( S 31 S 22 - S 32 S 21 - \frac{S 34 S 42 S 21 {Γ}_{CT}}{1 - S 44 {Γ}_{CT}} ) {Γ}_{L}}$$

If the Γ_{L} coefficient is approximated to zero, then b2 may not be affected by load variations (or Γ_{L}). The Γ_{L} coefficient equates to zero in the following equation:

$$S 31 S 22 - S 32 S 21 - \frac{S 34 S 42 S 21 {Γ}_{CT}}{1 - S 44 {Γ}_{CT}} = 0$$

$$and \text{:}$$

$${Γ}_{CT} = \frac{S 22 - S 21 / D}{S 44 ( S 22 - S 21 / D ) + S 34 S 42 S 21 / S 31} ≅ \frac{S 22 - S 21 / D}{S 34 * S 42 * S 21 / S 31}$$

The significance of the equation for Γ_{CT} above is that Γ_{CT} (i.e., the termination of the coupler isolation port) can be employed to offset non-ideal factors (mainly non-ideal S22 and finite directivity D). Γ_{CT} equal to zero (e.g., 50 ohm termination at coupler isolation port) may therefore not be the best option if S22·0. In other words, a 50-ohm coupler termination may not be the best choice if the RF OUT port is not perfect.

To address the referenced inadequacy of a real 50 or 75-Ohm termination impedance, a tuned complex impedance may be used to improve coupler performance. In certain embodiments, two independent tuners can be used to systematically tune the coupler termination and minimize power variations. For example, one tuner may be positioned at the coupler termination port and the other at load port. Proper coupler termination Γ_{CT} can reduce power variation caused by non-ideal S22 and coupler directivity. In certain embodiments, a complex load at the isolation port of a directional coupler is used to compensate for certain non-ideal factors in PA FEMs.

The coupler termination module 402 may comprise one or more passive devices, such as capacitors and/or inductors, which may provide passive frequency-selective impedance based on the frequency-dependent impedances presented by such devices. In another embodiment, the coupler termination module may include a diplexer 407 for actively selecting circuits having different impedances for different operational bands.

In certain embodiments, a resistor-capacitor (RC) circuit, resistor-inductor (RL) circuit, and/or RLC circuit may be used to provide a complex termination for a directional coupler. FIG. 5 illustrates possible coupler error load-pull result for an RF system. For example, the graph of FIG. 5 may correspond to a VSWR value of approximately 2.5 at the RF output port and duplexer mismatch. The graph provides the coupler error contour at the plane of the coupler termination port. A lower contour 510 illustrates a coupler error contour for low-band (LB) performance. The graph shows a best optimized error of approximately 0.34 for low-band performance at the complex impedance identified by reference m15. An upper contour 520 illustrates a coupler error contour for high-band (HB) performance. The graph shows a best optimized error of approximately 0.14 for high-band performance at the complex impedance identified by reference m20.

The following process may be utilized to tune the complex termination impedance with, for example, one 800 MHz band (LB) coupler and one 1.98 GHz band (HB) coupler: A lump coupler model (e.g., daisy-chain) may be created and simulated for high and low-band performance with a standard 50-Ohm termination impedance. The load pull results may be used to find the optimization load for each band. An adaptive load may be constructed to match optimized performance results for both high and low bands. Once the adaptive complex load has been applied to the system, results may be verified to confirm improved performance vis-à-vis 50-Ohm performance. While certain embodiments are described in the context of 2-band systems, adaptive coupler loads may be applied to systems accommodating any number of bands of operation.

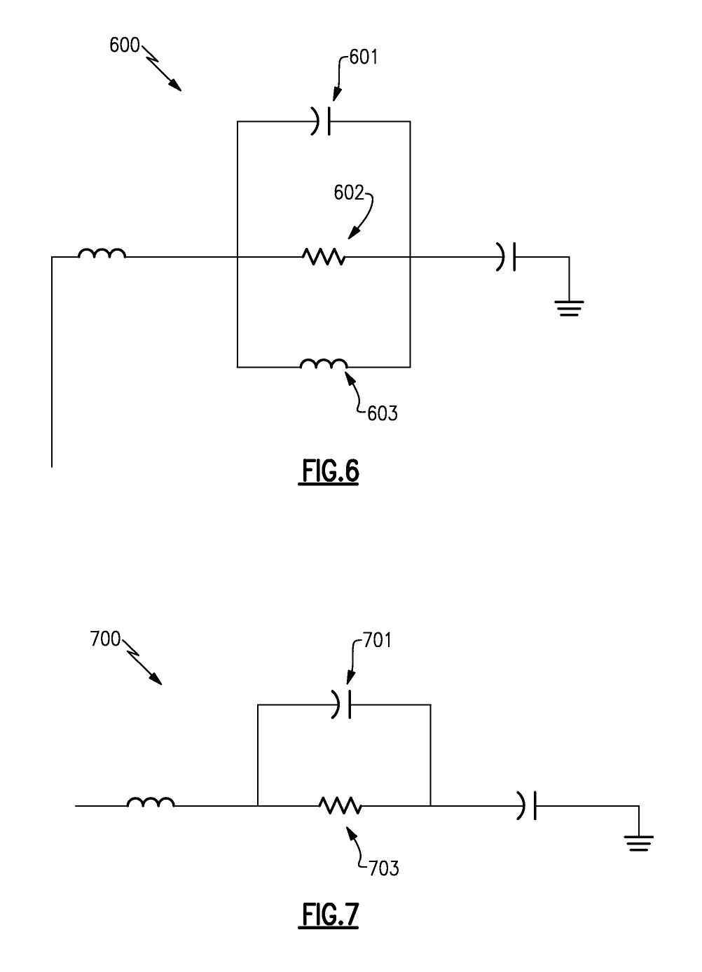

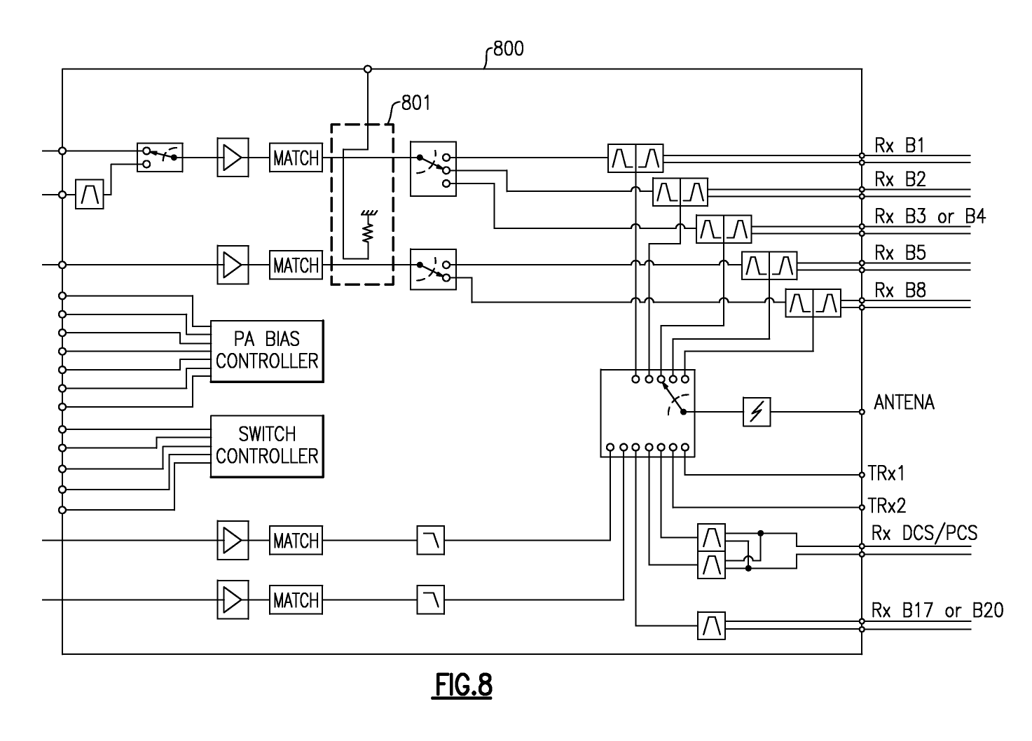

FIG. 6 provides an example adaptive load circuit for providing reduced coupler error for multiple bands. The circuit 600 includes a capacitor 601, a resistor 602 and an inductor 603. As the inductor and capacitor have frequency-varying impedances, the impedance of the circuit 600 may vary for signals of different frequencies. Therefore, the values of the capacitor 601, resistor 602, and/or inductor 603 may be selected to achieve the desired complex impedance for the bands of interest. In certain embodiments, the capacitor 601 is configured to resonate with the inductor 603 at certain frequencies of interest to provide the desired impedance. FIG. 7 illustrates a simplified impedance circuit 700 including a single capacitor or inductor 701 (shown as a capacitor) in parallel with a resistor 702. The impedance circuits 600, 700 may further comprise one or more series devices, such as inductors and/or capacitors, as shown.

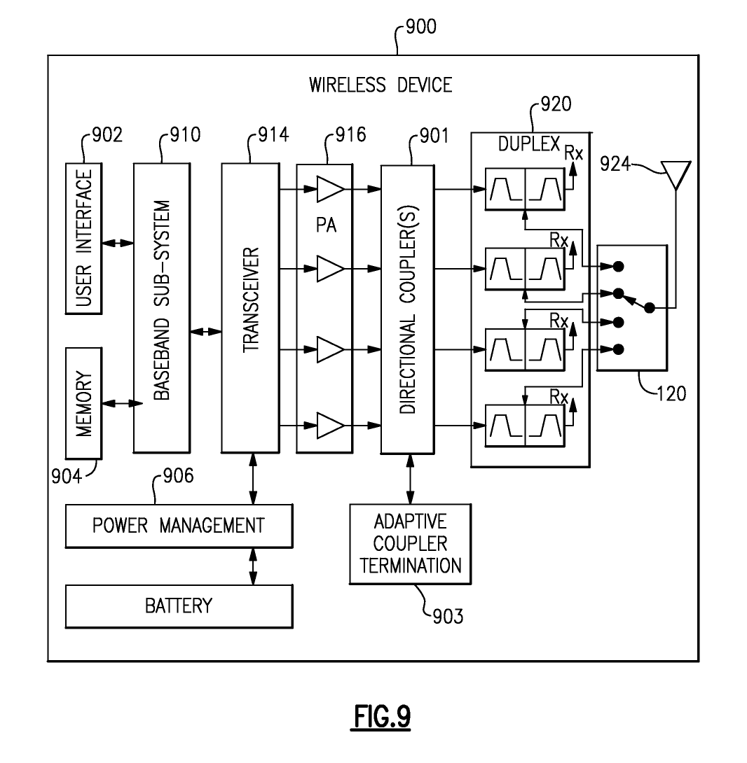

FIG. 8 is a block diagram of a multimode, multiband (MMMB) front end module incorporating a directional coupler 801 that may be connected to an termination circuit providing adaptive complex impedance as described herein. The module 801 may include circuitry for accommodating any desirable number of operational bands, as discussed in greater detail above.

The various embodiments disclosed herein provide solutions for developing wide band termination for directional couplers in RF FEMs to adaptively match multiple operational bands. Solutions disclosed herein may provide improved coupler error performance for each of multiple bands in a MMMB. In certain embodiments, improvement for at least one of low-band and high-band performance may be achieved in the range +/−0.6 dB.

### Wireless Device Implementation

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 9 schematically depicts an example wireless device 900 having one or more advantageous features described herein. In the context of various switches and various biasing/coupling configurations as described herein, a switch 120 and can be part of a module. In some embodiments, such a switch module can facilitate, for example, multi-band multi-mode operation of the wireless device 900.

In the example wireless device 900, a power amplifier (PA) module 916 having a plurality of PAs can provide an amplified RF signal to the switch 120 (via a duplexer 920), and the switch 120 can route the amplified RF signal to an antenna. The PA module 916 can receive an unamplified RF signal from a transceiver 914 that can be configured and operated in known manners. The transceiver can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexer 920 can allow transmit and receive operations to be performed simultaneously using a common antenna (e.g., 924). In FIG. 9, received signals may be routed to “Rx” paths (not shown) that can include, for example, a low-noise amplifier (LNA).

A number of other wireless device configurations can utilize one or more features described herein. For example, a wireless device may not necessarily be a multi-band device. In another example, a wireless device can include additional antennas such as diversity antenna, and additional connectivity features such as Wi-Fi, Bluetooth, and GPS.

The wireless device 900 includes one or more directional couplers 901 terminated by an adaptive load 903, as described herein. While various embodiments of MMMB front-end modules have been described, it will be apparent to those of ordinary skill in the art that many more embodiments and implementations are possible. For example, embodiments of integrated FEMs are applicable to different types of wireless communication devices, incorporating various FEM components. In addition, embodiments of FEMs are applicable to systems where compact, high-performance design is desired. Some of the embodiments described herein can be utilized in connection with wireless devices such as mobile phones. However, one or more features described herein can be used for any other systems or apparatus that utilize of RF signals.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar nature, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A directional coupler comprising:
a first port configured to receive a radio-frequency (RF) signal;
a second port connected to the first port via a first transmission line and configured to provide an RF output signal;
a third port connected to a second transmission line, the second transmission line coupled to the first transmission line; and
a termination circuit connected to the second transmission line and configured to provide a first impedance when the RF signal is within a first frequency band and provide a second impedance when the RF signal is within a second frequency band.

2. The directional coupler of claim 1 wherein the termination circuit includes first and second passive devices that are configured to resonate at a frequency within the first frequency band.

3. The directional coupler of claim 2 wherein the first passive device is a resistor and the second passive device is a capacitor.

4. The directional coupler of claim 2 wherein the first passive device is a resistor and the second passive device is an inductor.

5. The directional coupler of claim 2 wherein the termination circuit further includes a third passive device in parallel with the first and second passive devices.

6. The directional coupler of claim 5 wherein the first passive device is a resistor, one of the second and third passive devices is a capacitor and another of the second and third passive devices is an inductor.

7. The directional coupler of claim 1 wherein the first and second impedances are complex impedances.

8. The directional coupler of claim 1 wherein the termination circuit includes a diplexer for selectively connecting the second transmission line to the first or second impedance.

9. A radio-frequency (RF) system comprising:
a directional coupler configured to provide an RF output signal on a first port of the directional coupler;
a power amplifier module connected to a second port of the directional coupler;
power detection circuitry connected to a third port of the directional coupler; and
a termination circuit connected to a fourth port of the directional coupler and configured to provide a first impedance when the RF output signal is within a first frequency band and provide a second impedance when the RF signal is within a second frequency band.

10. The RF system of claim 9 wherein the termination circuit includes first and second passive devices that are configured to resonate at a frequency within the first frequency band.

11. The RF system of claim 10 wherein the first passive device is an inductor and the second passive device is a capacitor.

12. The RF system of claim 10 wherein the termination circuit further includes a third passive device in parallel with the first and second passive devices.

13. The RF system of claim 12 wherein one of the first and second passive devices is a capacitor and another of the first and second passive devices is an inductor and the third passive devices is a resistor.

14. The RF system of claim 9 wherein the first and second impedances are complex impedances.

15. The RF system of claim 9 wherein the termination circuit includes a diplexer for selectively connecting the second transmission line to the first or second impedance.

16. A wireless device comprising:
a transceiver configured to process RF signals;
an antenna in communication with the transceiver configured to facilitate transmission of an RF output signal; and
a directional coupler configured to provide the RF output signal to the antenna on a first port of the directional coupler;
a power amplifier module connected to a second port of the directional coupler;
power detection circuitry connected to a third port of the directional coupler; and
a termination circuit connected to a fourth port of the directional coupler and configured to provide a first impedance when the RF output signal is within a first frequency band and provide a second impedance when the RF signal is within a second frequency band.

17. The wireless device of claim 16 wherein the termination circuit includes first and second passive devices that are configured to resonate at a frequency within the first frequency band.

18. The wireless device of claim 17 wherein the first passive device is a capacitor and the second passive device is an inductor.

19. The wireless device of claim 17 wherein the termination circuit further includes a third passive device in parallel with the first and second passive devices.

20. The wireless device of claim 16 wherein the termination circuit includes a diplexer for selectively connecting the second transmission line to the first or second impedance.
